(19) United States
(12) Patent Application Publication
(10) Pub. No.: US 2025/0160088 A1
(43) Pub. Date: May 15, 2025

(54) OPTOELECTRONIC MICRODEVICE

(71) Applicant: VueReal Inc., Waterloo (CA)

(72) Inventors: Gholamreza CHAJI, Waterloo (CA); Ehsanollah FATHI, Waterloo (CA); Danish BAIG, Waterloo (CA)

(73) Assignee: VueReal Inc., Waterloo, ON (CA)

(21) Appl. No.: 18/839,300

(22) PCT Filed: Dec. 12, 2023
(86) PCT No.: PCT/CA2023/051641

§ 371 Date: Aug. 16, 2024

Related U.S. Application Data
(60) Provisional application No. 63/493,432, filed on Mar. 31, 2023.
(60) Provisional application No. 63/431,839, filed on Dec. 12, 2022.

(51) Int. Cl. H10H 29/03; H01L 21/683; H01L 25/075; H10H 29/24

(52) U.S. Cl. CPC H10H 29/03; H01L 21/6835; H01L 25/0753; H10H 29/24; H01L 2221/68309; H01L 2221/68354; H01L 2221/68368

(57) ABSTRACT

The present disclosure relates to development of microdevices on a substrate that can be released and transferred to a system substrate. The disclosure further relates to methods to integrate anchors to hold a microdevice to a substrate. The microdevices are in different configurations with respect to anchors, release layers, buffers layers and substrate.

### BACKGROUND AND FIELD OF THE INVENTION

The invention relates to the development of microdevices on a substrate that can be released and transferred to a system substrate.

### SUMMARY

The present invention relates to a method to integrate anchors to hold a microdevice to a substrate, the method comprising, forming at least two diaphragm layers on the substrate such that the at least two diaphragm structures fit under a microdevice surface wherein a diaphragm structure is smaller than the microdevice surface in at least one dimension, and bonding the microdevice surface to the diaphragm structures with a bonding layer.

The present invention also relates to a method to transfer microdevices with a formation of diaphragm, the mythos comprising, fabricating a cartridge diaphragm on a cartridge substrate, inspecting the cartridge substrate to identify defective areas before the transfer; and identifying good areas based on a number or type of defects per area.

The present invention also relates to a method to fabricate microdevices on a microdevice substrate, the method comprising, having zones that have a same size or are multiple times smaller than islands in a cartridge substrate, inspecting microdevices for defects and performance based on predefined parameters, and separating the microdevice zones are separated from wafers and wherein each zone is binned into different groups based on end product performance requirements.

The present invention also relates to a method to populate cartridge islands, the method comprising, aligning a microdevice zone substrate with an area of good cartridge island in the cartridge substrate, having two substrates get closer so that microdevices bond to a cartridge diaphragm structure by a bonding material and having a release layer between microdevices and a zone substrate wherein the release layer is delaminated by either chemical, laser, thermal or a mechanical process, leaving the bonded microdevices on the diaphragm structure.

The present inventions also relates to a method to integrate anchors to hold a microdevice to a cartridge substrate, the method comprising, depositing release layer on the cartridge substrate, forming openings in the release layers, depositing and patterning an anchor and diaphragm layer, extending at latest part of the diaphragm layer to the release layer opening, and forming and patterning a bonding layer on top of the diaphragm layer.

The present invention also relates to a method to transfer microdevices, the method comprising, developing a mesa structure on a donor substrate, with microdevice structures formed by etching through different layers, a first bottom conductive layer, functional layers, and a second top conductive layer, depositing a top contact pad before or after the etching on top of the second top conductive layer, wherein a top contact pad is deposited before or after the etching on top of the second top conductive layer and each microdevice includes passivation layers and/or MIS layer surrounding each microdevice for isolation and/or protection, and providing the microdevices with different anchors whereby after a liftoff of the microdevices, an anchor holds a microdevice to the donor substrate.

### BRIEF DESCRIPTION OF THE DRAWINGS

The foregoing and other advantages of the disclosure will become apparent upon reading the following detailed description and upon reference to the drawings.

FIG. 1A illustrates a cross-sectional view of microdevices with different anchors in a filling layer.

FIG. 1B illustrates a cross-sectional view of microdevices after post processing the filling layer.

FIG. 1C illustrates a top view of the microdevices of FIG. 1B.

FIG. 1D illustrates a cross-sectional view of the transfer step used for transferring the microdevices to another substrate.

FIG. 1E illustrates a cross-sectional view of transferred microdevices to the substrate.

FIG. 2A shows the microdevices on a substrate and a release layer covering part of the microdevices.

FIG. 2B shows the microdevices are held to the substrate through the anchors after the release layers are deactivated or removed.

FIG. 2C shows the first substrate and buffer layer are removed from the microdevices.

FIG. 2D shows a release layer being deposited and patterned.

FIG. 3A shows a case of offsetted anchors.

FIG. 3B shows another case of offsetted anchors.

FIG. 4A shows a microdevice formed on top of a stage.

FIG. 4B shows the top view of the structure in FIG. 4A.

FIG. 5A shows an anchor is formed on top of a substrate.

FIG. 5B shows the top view of the example of FIG. 5A.

FIG. 5C shows where the main part of the anchor and release layer are under the microdevice.

FIG. 6 shows the top view of another related embodiment for integrating anchors.

FIG. 7A shows a smaller diaphragm structure/layer is formed on the substrate.

FIG. 7B shows another related example of the diaphragm structure for microdevice transfer.

FIG. 7C shows an example of patterning of the release layer on substrate.

FIG. 8 shows a related embodiment related to the formation of diaphragm-based microdevice transfer.

FIG. 9A shows an exemplary process step for populating the cartridge islands.

FIG. 9B The process can continue with the remaining microdevices on the same zone substrate or a completely different zone substrate with the same or different microdevices.

FIG. 9C the microdevices are coupled to the zone substrate through a patterned release layer.

FIG. 9D shows an embodiment where the exposed areas are covered by a protective layer.

FIG. 10A shows examples of cartridge islands having different shapes than squares or rectangles.

FIG. 10B shows an example where zones are aligned, and enough zones are used to cover the entire surface of the cartridge island.

The present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

Microdevices can be microLED, OLED, microsensors, MEMs, and any other type of devices.

The invention below describes a method and structures involved in microdevice transfer.

In one related embodiment, stages are formed on the donor substrate, and microdevices are coupled to the stage through adhesive or release layer. An anchor can be holding the microdevices to the stage temporarily. The donor substrate can be aligned with a receiver substrate and a selected set of microdevices are bonded to the receiver substrate. The donor and receiver substrates are moved away and a selected set of microdevices are transferred to the receiver substrate. Here, the adhesive, release layer or anchor force is weaker than the bonding of the microdevices to the receiver substrate.

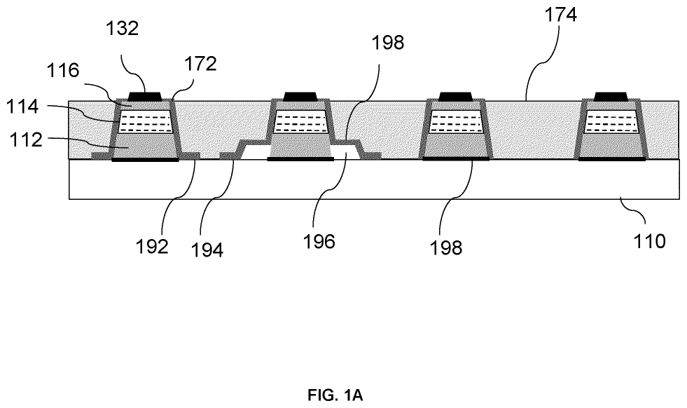

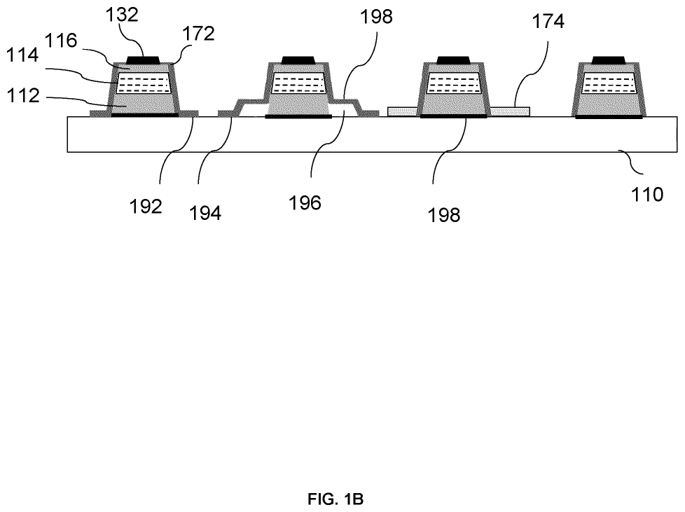

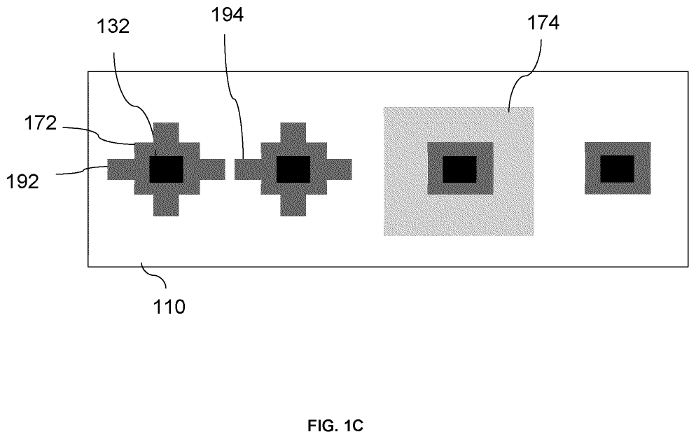

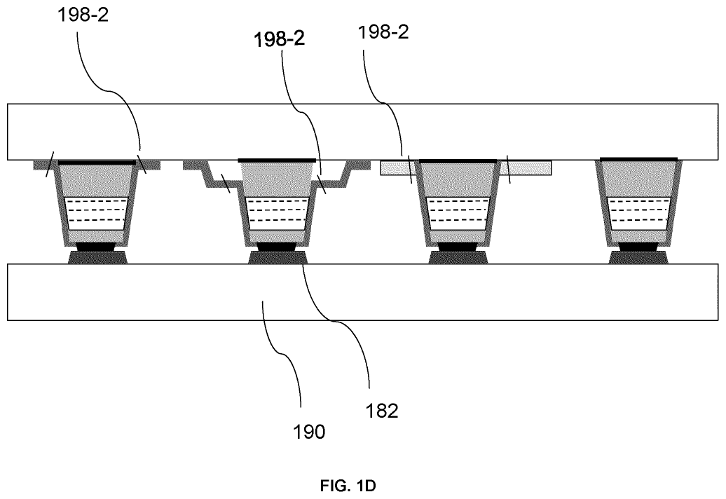

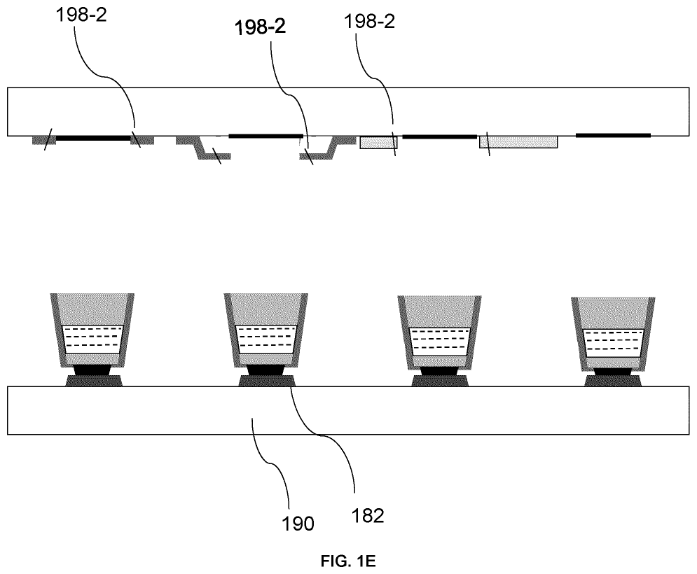

In another embodiment shown in FIG. 1A, a mesa structure is developed on a donor substrate 110, as hereinbefore described, with microdevice structures formed by etching through different layers, e.g., a first bottom conductive layer 112, functional layers, e.g., light-emitting, 114, and a second top conductive layer 116. A top contact pad 132 may be deposited before or after the etching on top of the top conductive layer 116. Also, each microdevice may include other passivation layers and/or MIS layer 172 surrounding each microdevice for isolation and/or protection. In this embodiment the microdevices may be provided with different anchors, whereby after liftoff of the microdevices, the anchor holds the microdevice to the donor substrate 110. The lift off may be done by laser. In an example, only the microdevices are scanned by a laser. In an embodiment a mask may be used that has an opening for the microdevice only at the back of the donor substrate 110 to block the laser from the other area. The mask can be separate or part of the donor substrate 110. In another case, another substrate can be connected to the microdevices before the liftoff process to hold the microdevices. In another case, a filler layer 174, e.g., dielectric, may be used between the microdevices.

In a first illustrated case, a layer 192 is provided to hold the microdevice to the donor substrate 110. The layer 192 may be a separate layer or part of the layers of the microdevices that are not etched during development of mesa structure. In another case, layer 192 may be the continuation of one of layer 172. In this case, the layer 192 may be either a metal or dielectric layer (SiN or SiO2, or other materials). In another case, the anchor is developed as a separate structure comprising extensions 194, a void/gap 196, and/or a bridge 198. Here, a sacrificial layer is deposited and patterned with the same shape as the gap/void 196. Then the anchor layer is deposited and patterned to form the bridge 198 and/or the extension 194. The sacrificial material may be removed later to create the void/gap 196. One can avoid the extension 194 as well. Similar to the previous anchor 192, another anchor may be made of different structural layers. In another case, the filling layers 174 act as anchor. In this case, the filling layers 174 can be etched or patterned or left as it is.

FIG. 1B illustrates the samples after removing the filler layer 174 and/or etching the filler layer to create the anchor. In another case, the adhesive force of the bridge layer 198 after liftoff is enough to hold the microdevice in place and act as an anchor. The final microdevice is on the right side of the substrate 110. Here, after liftoff, some residue may stay under the microdevice acting as an adhesive bridge layer 198.

FIG. 1B is shown in one substrate 110 for illustration purposes only. One can use either one or combination of them in a substrate.

As shown in FIG. 1C, the anchor may be covering at least a portion of or the entire periphery of the microdevice or can be patterned to form arms 194 and 192. Either of the structures may be used for any of the anchor structures.

FIG. 1D illustrates one example of transferring the microdevices to a receiver substrate 190. Here the microdevices are bonded to the pads 182 or placed in a predefined area without any pads. The pressure force or separation force may release the anchor by breaking them. In another case, temperature may also be used to release the anchor. The viscosity of the layer between lift off of the microdevice and donor substrate 110 may be increased to act as an anchor by controlling the temperature. FIG. 1E illustrates the microdevices after being transferred to the receiver substrate 190 and shows the possible release point 198-2 in the anchors. The anchor may also be directly connected to the donor substrate 110 or indirectly through other layers.

The microdevices on donor substrate may be developed to have two contacts on the same side facing away from the donor substrate 110. In one case, the microdevices may be transferred to the receiver substrate 190 directly from the donor substrate 110. Here, the contacts on the same side facing away from the donor substrate 110 may be bonded directly to the receiver substrate pads 182. The microdevices may be tested either in the donor 110 or in the cartridge substrate. In another embodiment, the microdevices may be transferred to a cartridge substrate first from the donor substrate 110 prior to being transferred to the receiver substrate 190. Here, the contacts on the same side facing away from the donor substrate 110 will not be directly bonded to the receiver substrate 190, i.e. the receiver substrate 190 does not need to have special pads 182. In this case, conductive layers are deposited and patterned to connect the contacts to proper connection in the receiver substrate 190.

In one case, the microdevice has a functional body and contacts. The contacts can be electrical, optical or mechanical contacts.

In the case of optoelectronic microdevices, the microdevice can have functional layers and charge carrying layers. Where charge carrying layers (doped layers, ohmics and contacts) transfer the charges (electron of hole) between the functional layers and contacts outside the microdevice. The functional layers can generate electromagnetic signals (e.g., lights) or absorb electromagnetic signals.

System substrates can have pixels and pixel circuits that each pixel controls at least one microdevice. Pixel circuits can be made of electrodes, transistors, or other components. The transistors can be fabricated with a thin film process, CMOS, or organic materials.

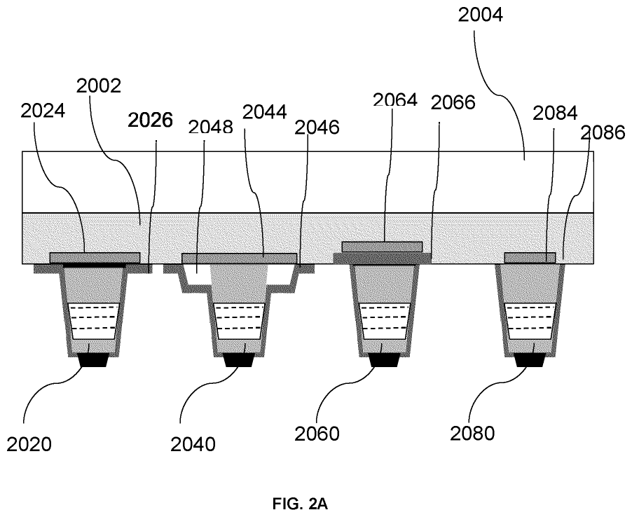

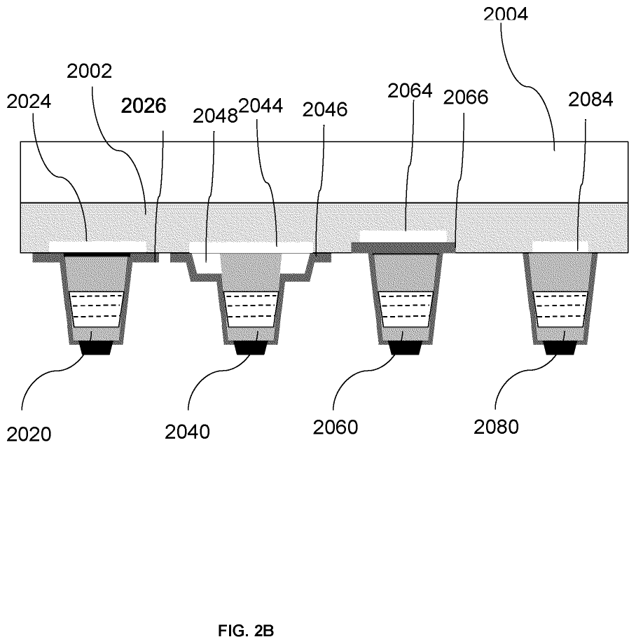

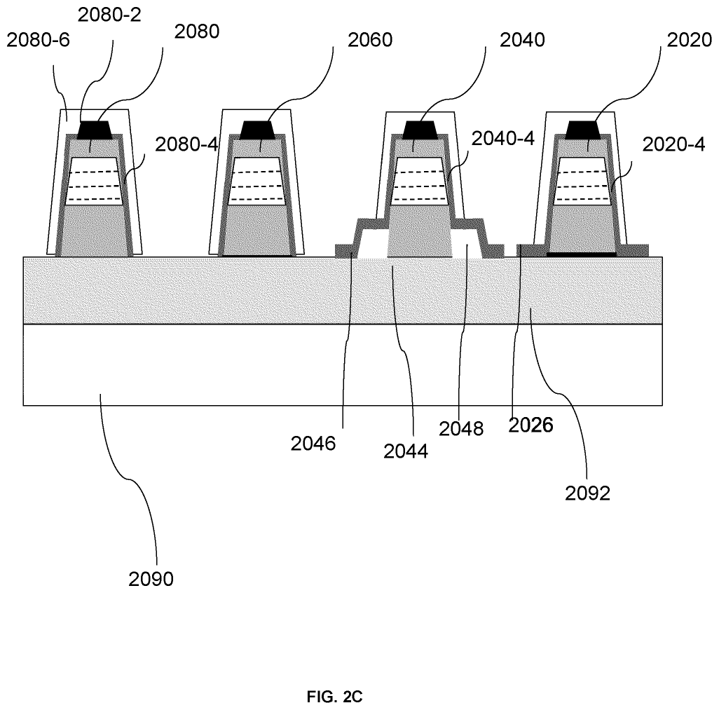

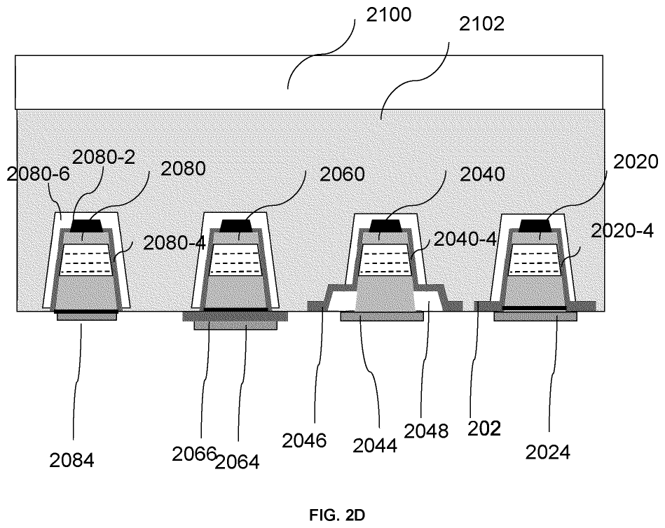

In one embodiment, as shown in FIG. 2A, the microdevice (2020, 2040, 2060, 2080) is on a substrate 2004 and a release layer (2024, 2044, 2064, 2084) at least covers part of the microdevice (2020, 2040, 2060, 2080) surface facing the substrate 2004. There can be a buffer layer 2002 between the substrate 2004 and microdevice (2020, 2040, 2060, 2080). In one case, at least one anchor (2026, 2046, 2066, 2086) holds the microdevice (2020, 2040, 2060, 2080) to the substrate or buffer layer.

In one case, the anchor 2026 is formed as an extension of a layer covering at least part of the microdevice 2020. Here, part of the anchor is not covered by the release layer 2024 so it is coupled to the buffer or substrate layer.

In another related case, there is a gap 2048 between the extension layer forming the anchor 2046 and at least part of the microdevice 2040.

In another related case, the anchor 2066 is formed as a layer covering at least part of the microdevice 2060 surface facing the substrate 2004.

In another case, the anchor 2086 is formed as part of the microdevice 2080. Here, the release layer 2084 is not covering part of the surface of the microdevice 2080 facing the substrate 2004. As a result, the part not covered 2086 can couple to the substrate or buffer layer. Here, the buffer layer can be adhesive, polymer, or metal.

After the release layers are deactivated or removed, as shown in FIG. 2B, the microdevices (2020, 2040, 2060, 2080) are held to the substrate through the anchors. The microdevices can be now transferred to a system substrate as explained in FIG. 1A-1E.

The release layer can be deactivated optically, chemically, thermally, or mechanically.

In case of chemical deactivation or removal, part of the release layer is exposed so that the chemical (e.g., solvent, etchant, or other chemicals) can penetrate and remove the release layer.

In case of an optical release layer, the substrate is transparent to a specific wavelength that can deactivate the release layer.

One method of developing microdevices ready for transferring microdevices into a system substrate is described in FIGS.′ 2C-2D.

In one step, at least one microdevice 2080, 2060, 2040, 2020 is formed on the first substrate 2090. The microdevices can have pads 2080-2 allowing electrical connection to the microdevices on the top side (the top side is the side away from the first substrate). The microdevices can be covered by passivation layers 2080-4. In addition, the microdevice can be covered by a protection layer 2080-6 that protects microdevices from the subsequent steps (part of the protection layer can be removed after the process is completed). In one related case (2040, 2020), part of the passivation layers 2040-4, 2020-4 can be patterned to form anchors 2046 and 2026. In one case, a void structure is formed 2048 under part of the anchor. There can be a buffer layer 2092 between the microdevices and substrate.

The microdevices are bonded to a second substrate 2100 using a bonding layer 2102 and planarization layer 2102 (The two layers can be the same). As demonstrated in FIG. 2C, the first substrate 2090 and buffer layer 2092 are removed from the microdevices. Here, the anchor layer is deposited 2066 (it can be patterned at this stage). The anchor layer 2066 can be dielectric or metal or other types of materials. As shown in FIG. 2D, a release layer is deposited 2024, 2044, 2064, 2084 and patterned. The release layer is extended at least from part of the microdevice edge 2042. The anchor layer 2066 can be a combination of multiple layers or one layer. The anchor layer 2066 can be changing under different conditions such as temperature, electrical bias, or lights to push the microdevices forward. The microdevices can have pads on the bottom side as well and can have passivation layers (The passivation and anchor layers can be the same).

As demonstrated in FIG. 2A microdevices can be bonded to a third substrate 2004 and removed from the second substrate.

The planarization and first bonding layer are removed. The anchors can be patterned at this stage if it is not patterned. To protect the microdevices during removal of the release layer (FIG. 2B), the microdevices can be covered by a second protection layer. The second protection layer can be photoresist.

To pack microdevices close to each other for higher utilization of original wafers, the anchors need to be modified. In one case, an anchor of a microdevice and an anchor of its adjacent microdevices on a donor/cartridge substrate, are offsetted from each other to provide more room for integration of anchors. In another related case, the anchors are formed on the sidewall of a stage. In another case, the stage and the anchor structure are formed underneath the microdevice.

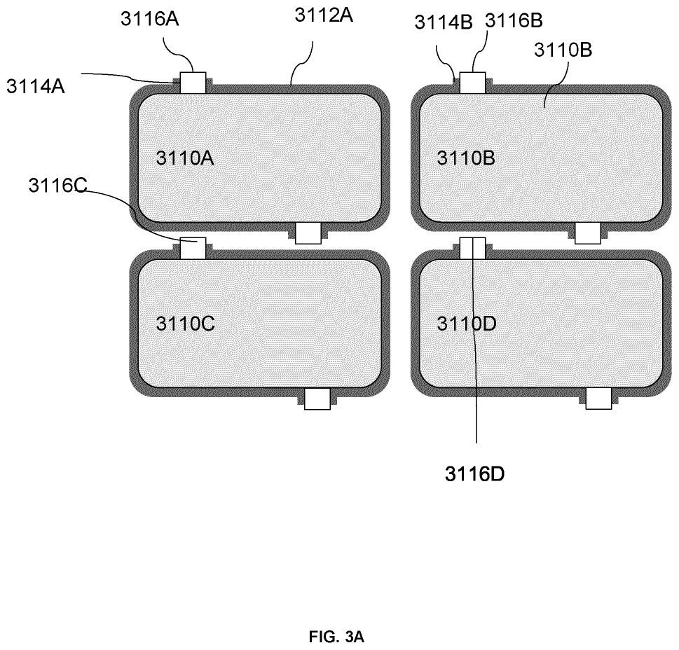

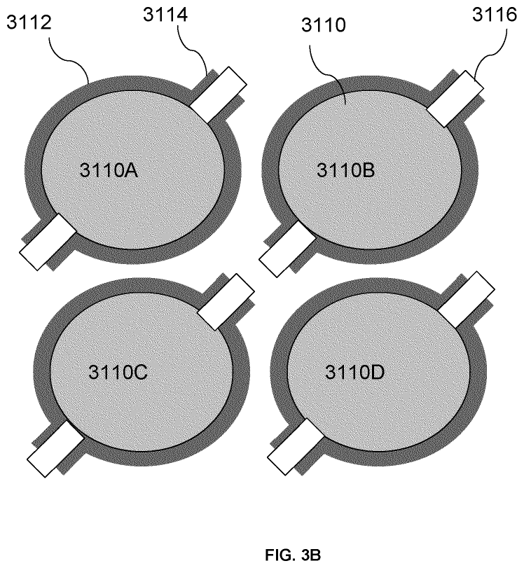

FIG. 3A shows an exemplary case of offsetted anchors. Microdevices 3110A and 3110C are adjacent to each other on a donor/cartridge substrate. The anchors 3116 A, B, C, and D and 3114 A, B, C, and D (the anchors are repeated for each microdevice 3110 A, B, C, and D and the numbering also includes the anchor labels A, B, C, and D) are formed around the microdevice. The release layer 3112A formed under the microdevice 3110A (the microdevice and microdevice structures are repeated for each microdevice 3110A, B, C, and D and the numbering also includes the microdevice labels A, B, C, and D). Here, for example, the anchors 3114B and 3116C are offsetted.

FIG. 3B shows another example of offsetted anchors. Microdevices 3110A and 3110C are adjacent to each other. The anchors 3116A and 3114A are formed around the microdevice. The release layer 3112 formed under the microdevice 3110A (the microdevice and microdevice structures (anchors) are repeated for each microdevice 3110A, B, C, and D, and the numbering also includes the microdevice/anchor labels A, B, C, and D). Here, for example, the anchors 3114A and 3116C are offsetted.

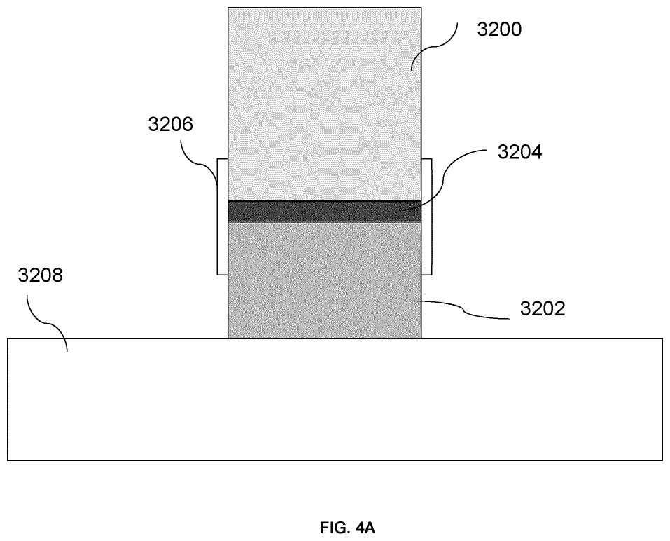

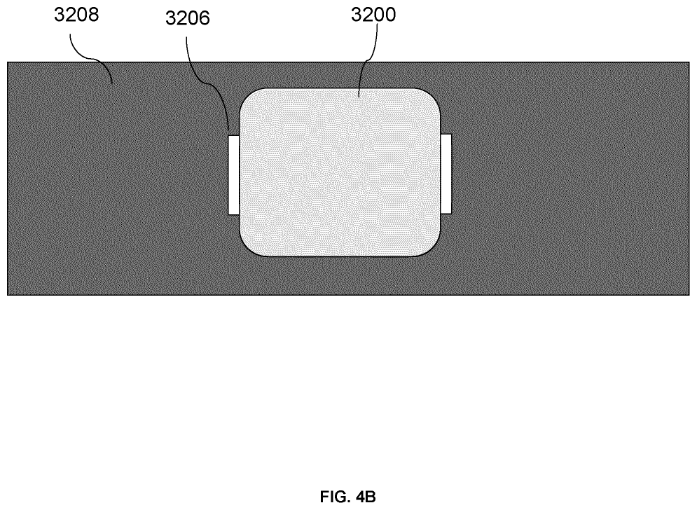

Another related example is presented in FIG. 4A. Here, microdevice 3200 is formed on top of a stage 3202. There is a release layer 3204 coupling microdevice 3200 into the stage 3202. The release layer can be adhesive. In another related embodiment, the release layer can be multi-layer including an adhesive. The adhesive layer can be deactivated using different factors such as temperature, chemical, electrical, charge or so on. There can be other adhesive layers between microdevice 3200 and stage 3202. The stage 3202 can be polymer or dielectric or conductive. Anchor 3206 can be formed on part of microdevice 3200 and stage 3202. The structure is on a substrate 3208. The anchor 3206 can cover part of the other surface of microdevices 3200. The anchor 3206 can cover part of the surface of the substrate 3208. FIG. 4B shows the top view of the structure in FIG. 4A.

In another related embodiment, the stage is formed on a microdevice. Here the release layer is formed and patterned. After that, the stage material is formed. The stage can be deposited using different techniques such as printing, spray coating, PECVD, e-beam sputtering and so on. The stage is then bonded to the substrate 3208 and the microdevices are separated from the original substrate. In another related embodiment, the stage is formed on the substrate 3208. The stage can include the release layer and the adhesive layer. The stage is bonded to the microdevices using different techniques such as thermal compression. For all related embodiments, the anchor can be formed after the stage and the microdevices are coupled. Here, the anchor layer is deposited and patterned. The patterning can be liftoff, lithography, or etching (dry or wet).

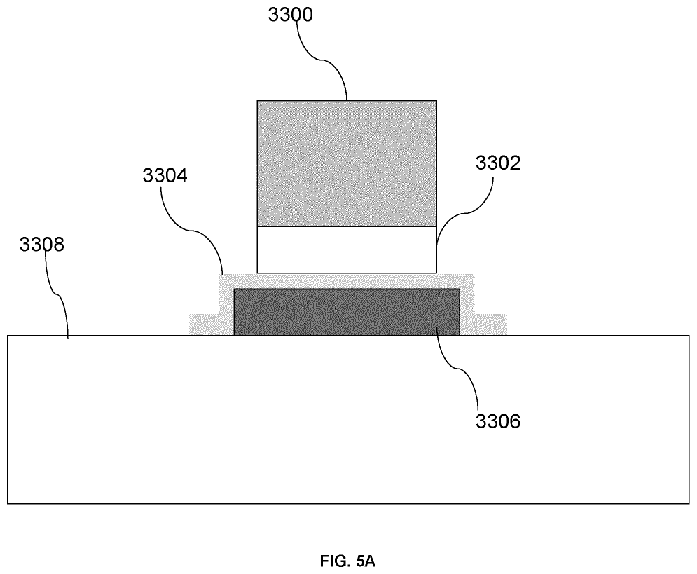

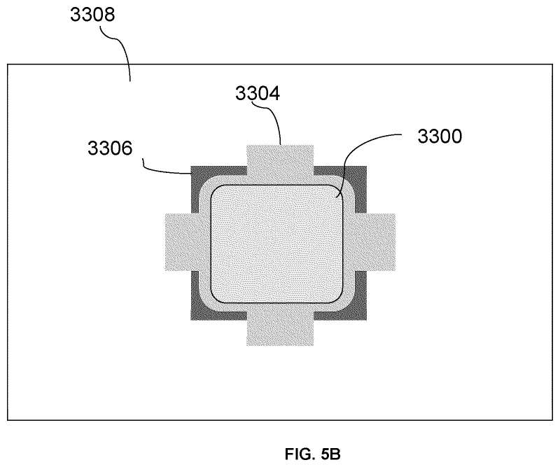

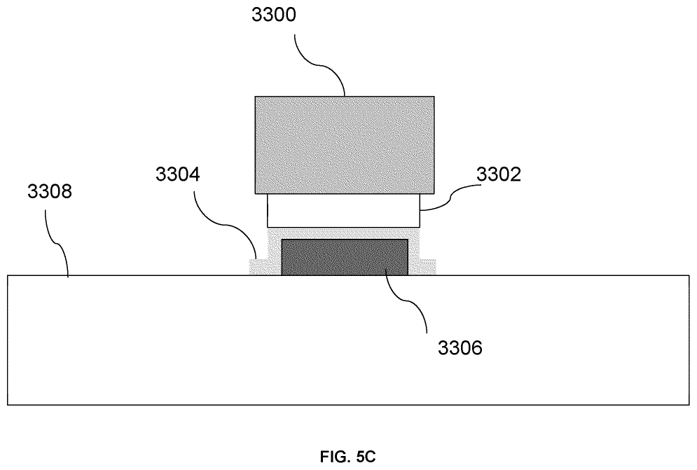

Another related example is presented in FIG. 5A. Here, an anchor 3304 is formed on top of a first stage 3306 on the substrate 3308 where part of the anchor is connected to the substrate. The first stage 3306 can include a release layer 3306 separates at least part of the anchor 3304 from the substrate 3308. There is a second stage formed on top of the anchor surface 3302. The second stage can consist of different layers, and it may include adhesive or dielectric or metal or different materials. In one related embodiment, the microdevice 3300 is coupled to the anchor structure 3304. Here, the microdevice 3300 is coupled to the anchor surface 3304 using the second stage (e.g., Adhesive, or bonding agent) 3302. In another related embodiment, the second stage is formed on the microdevices and bonded to the anchor surface 3304. After these related embodiments, the microdevices are separated from the original substrate after coupling to the anchor. The formation of the second stage (or at least part of it) can be selective. As a result, a selective set of microdevices are coupled with the anchor surface. To enable the transfer the release layer is removed or deformed so that the microdevice can be easily removed by breaking the anchor. FIG. 5B shows the top view of the example of FIG. 5A.

Another related example is presented in FIG. 5A. Here, an anchor 3304 is formed on top of substrate 3308. A release layer 3306 separates at least part of the anchor 3304 from substrate 3308. The microdevice 3300 is coupled to the anchor structure 3304. Here, the microdevice 3300 is coupled to the anchor 3304 using an adhesive or bonding agent 3302. The release layer is removed or deformed to enable the transfer so that the microdevice can be easily removed by breaking the anchor. FIG. 5B shows the top view of the example of FIG. 5A.

One method to form the anchor in FIG. 5A is to form the anchor and release layer in substrate 3308 and the microdevice is then bonded to the structure of the anchor using bonding layer 3302. In another method, the anchor and release layers are formed on the microdevice and then the microdevice with the structure is bonded to the substrate 3308.

FIG. 5C is the same example as FIG. 5A. Here, it shows where the main part of the anchor 3304 and release layer 3306 are under the microdevice 3300. As a result, the microdevices can be packed closer to each other.

In another related embodiment for FIG. 5C. At least part of the second stage is formed selectively. Here a selected set of microdevices are transferred from the original substrate to the donor substrate 3308 with the stage.

In another related embodiment for FIG. 5C, the anchor and the first stage are the same.

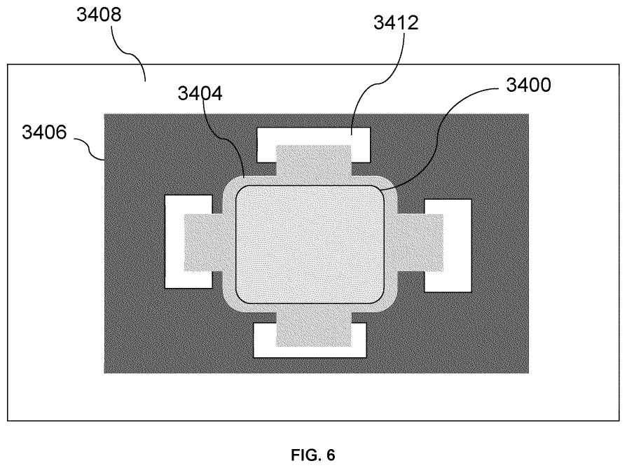

FIG. 6 shows the top view of another related embodiment. After the release layer 3406 is deposited on cartridge substrate 3408, openings 3412 are formed in the release layer 3412. The anchor and diaphragm layer 3404 is deposited and patterned. At least part of diaphragm layer 3404 extends to the release layer opening 3412. The anchor and diaphragm layer 3404 is deposited and patterned. At least part of diaphragm layer 3404 extends to the release layer opening 3412. A bonding layer 3400 is formed and patterned on top of the diaphragm layer 3404. A selected set of microdevices from a donor substrate are aligned with the bonding layer and bonded to it. The donor substrate is removed, and the selected microdevices remain on cartridge substrate 3408 through bonding patterns 3400. This process can be repeated, and other microdevices can be aligned and transferred to the cartridge substrate 3408. The microdevices can be different microdevices from different donor substrates. Before transferring the microdevices into a system substrate, the release layer is removed or deformed to enable the transfer. A set of selected microdevices coupled to the cartridge substrate 3408 through bonding layer 3400 is aligned with the landing area (or bond pads) on a system substrate. The microdevices are bonded to the system substrate through the bond pads. The selected set of microdevices is separated from the cartridge substrate 3408 by separating the anchor structure 3404 from the substrate during the bonding process of microdevices to the system substrate or while the cartridge substrate is moved away from the system substrate after bonding.

In FIGS. 5A-6, the bonding layer can form on the diaphragm (or anchor) layer or the microdevices on a donor substrate. The bonding pattern can be formed only for a selected set of microdevices that will be transferred to the cartridge substrate. In one case, the bonding layer 3404 is not patterned. After microdevices are transferred to the cartridge substrate, the microdevice or another layer covering the microdevice is used to pattern the bonding layer. As a result, the bonding layer will be self-aligned with the microdevice eliminating alignment errors.

The substrate in FIGS. 2, 3, 4, 5, 6 (all figure sub extensions) can have a stack of layers such as buffer layers. The anchor in FIGS. 2, 3, 4, and 5 (all figure sub extensions) can be developed using any methods described in this document or other approaches. The release layer can be a polymer, dielectric or metal. The anchor layer can be dielectric, polymer, or metal. The bonding layer can be pressure-sensitive adhesion, thermally cured adhesive, light-cured adhesive or normal polymer. The adhesive can be photo definable for patterning or etched to create the patterns. The adhesive layer can be larger or smaller than the microdevice. The etching can be dry or chemical etching.

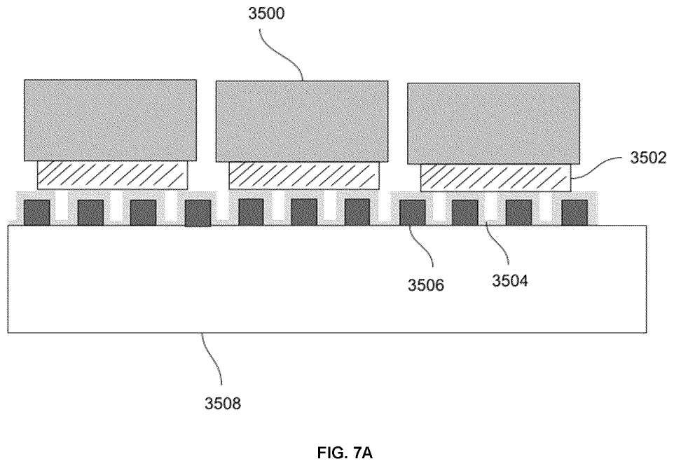

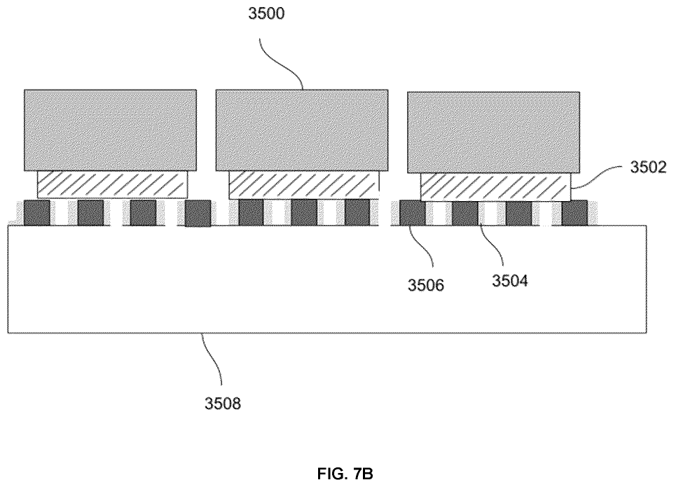

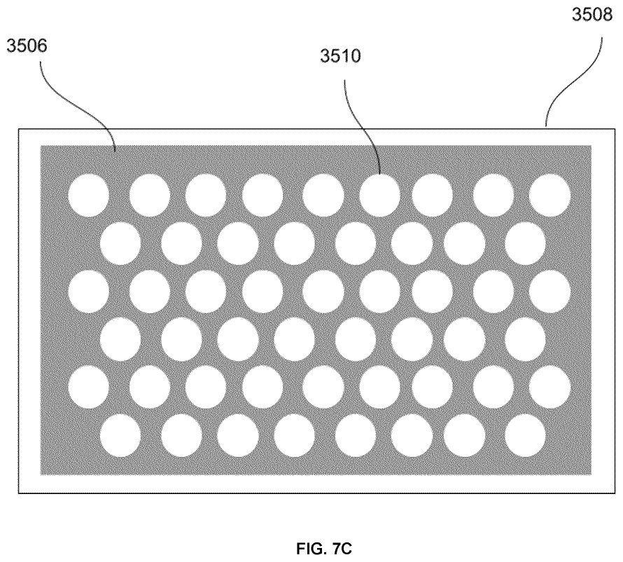

FIG. 7A shows another related example of the invention described here. In FIG. 7A, a smaller diaphragm structure/layer is formed on substrate 3508. The diaphragm is smaller than the microdevice 3500 surface in one dimension, so at least two diaphragms fit under the microdevice 3500. As a result, bonding the microdevice 3500 to the diaphragm structures with a bonding layer 3502 will require less alignment. The alignment accuracy requirement is reduced as the number of diaphragms per microdevice increases. One example of a diaphragm structure is formed by depositing a material layer 3504 on a patterned release layer 3506. The material and release layer can be dielectrics, metal, organic or other combinations. In one case, the diaphragm is the dielectric layer, and the release layer is metal. The bonding layer 3502 is formed either on the microdevice 3500 or the surface of the diaphragm 3504. The bonding layer can be a continuous layer, patterned to match the diaphragm pattern or patterned to match the microdevice. In one case, after the microdevice is bonded to the diaphragm structure, the bonding layer is etched and removed from the excess area not covered by the microdevice.

FIG. 7B shows another related example of the diaphragm structure for microdevice transfer. Here, the process is similar to FIG. 7A. After the formation of diaphragm layer 3504, the surface of the diaphragm is etched away leaving more pillar shape structures on the surface of the microdevice.

FIG. 7C shows an example of patterning 3510 of the release layer 3506 on substrate 3508. Here the pattern can be interleaved to have more of the diaphragm structure under each microdevice and assist in alignment accuracy. This pattern can be different for different shapes or orientations.

FIG. 8 shows a related embodiment related to the formation of diaphragm-based microdevice transfer. During step 3602, the cartridge diaphragm is fabricated on a cartridge substrate using one or more embodiments described or related embodiments. During the next step, 3604, the cartridge substrate is inspected, and the defective areas are identified. The inspection can be visual or use different optical techniques. The defect can be repaired with different techniques such as laser, fused ion beam (FIB), and other process techniques. In step 3606, the defective area is identified, and the good areas for transfer are chosen. The good area can be identified based on the number or type of defects per area. The cartridge substrate can have island areas of diaphragms. Each area can be populated with one or smaller of the same size area in the microdevice substrate. The size of the islands is also chosen to be compatible with the system substrate array, not causing interference during transfer with existing microdevices on the system substrate or existing pads.

During another step, 3612-(1:j), microdevices can be fabricated on a microdevice substrate. There can be more than one microdevice associated with on cartridge structure. The microdevices are fabricated so that there are zones that have the same size or are multiple times smaller than the islands in the cartridge substrate. The microdevices are inspected for defects and performance based on predefined parameters (step 3614-(1:j)). The microdevice zones are separated from the wafers, and each zone is binned into different groups based on the end product performance requirements (step 3616-(1:j)).

The microdevices zones associated with similar or one product are used to populate the good cartridge islands in the substrate during step 3620. The good area can be identified based on the number or type of defects per area. The transfer can be done selectively by populating part of the cartridge zone with part of the microdevices in one zone, or all the microdevices in the microdevice zones are transferred into the cartridge island. In both cases, the adhesive layer can be used to form bonding between the microdevice and the diaphragm layer in the cartridge island. The selected microdevices bonded to the diaphragm are separated from the zone substrate using different approaches (e.g. laser, light, chemical, mechanical, heat, or so on). The process can be repeated till the entire cartridge island is populated with one or different types of microdevices. The cartridge can go through different processes, such as removing the release layer, curing, modulation, and so on. Before or after each step, inspection steps 3622 can be done to identify the process defects. In one related embodiment for removing the release layer, a protective layer covers the microdevices and only leaves a small opening for the chemical to etch away the release layer.

After the final inspection, the cartridges are assigned to different applications based on performance metrics and defect rates 3624. The defect can be repaired or removed from the cartridge prior to transfer.

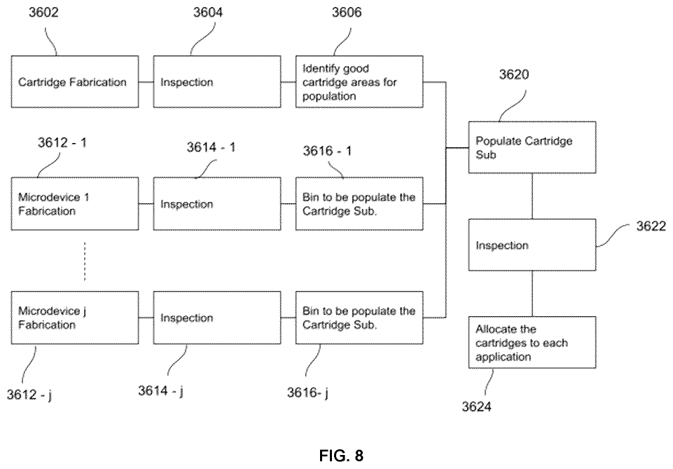

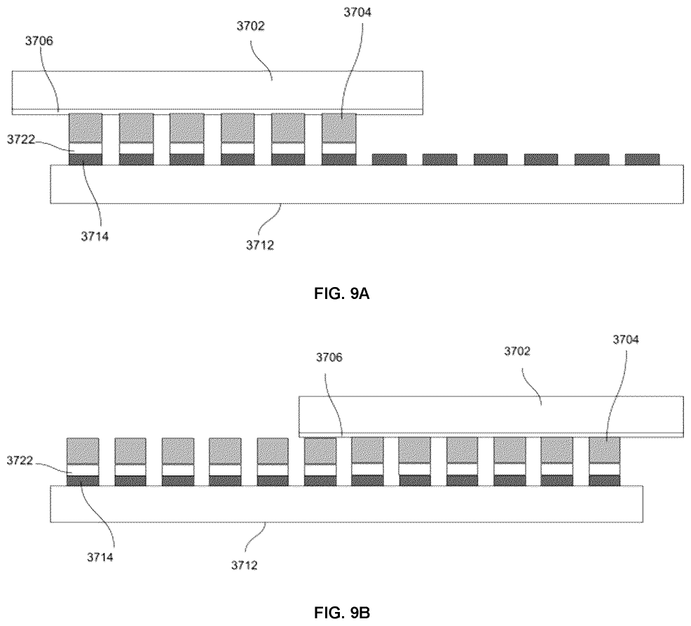

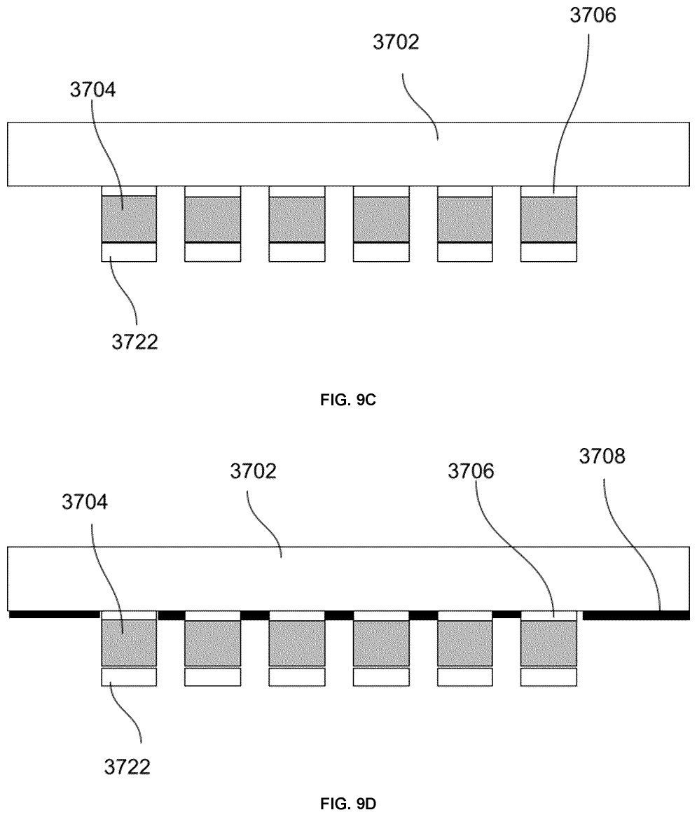

FIG. 9A shows an exemplary process step for populating the cartridge islands. Here, the microdevice zone substrate 3702 is aligned with an area of good cartridge island in the cartridge substrate 3712. The good area can be identified based on the number or type of defects per area. The two substrates get closer so that microdevices 3704 bond to the cartridge diaphragm structure 3714 by a bonding material 3722. Here, thermal, pressure, or light may be used to enable the bonding. There can be a release layer 3706 between microdevices 3704 and zone substrate 3702. The release layer can be delaminated by either chemical, laser, thermal or mechanical. Therefore, leaving the bonded microdevices on the diaphragm structure 3716. As demonstrated in FIG. 9B, The process can continue with the remaining microdevices 3704 on the same zone substrate 3702 or a completely different zone substrate with the same or different microdevices. In one related embodiment demonstrated in FIG. 9C, the microdevices 3704 are coupled to the zone substrate 3702 through a patterned release layer 3706. This reduces the residue of release layers getting deposited on the cartridge substrate. In one related embodiment, one can form the bonding layer 3722 on the microdevices. FIG. 9D shows an embodiment where the exposed areas are covered by a protective layer. This layer can protect the cartridge substrate from the laser if the release layer 3706 is the laser release layer. The protective layer 3708 can be on the top surface of substrate 3702 or the same surface as the microdevices are coupled with.

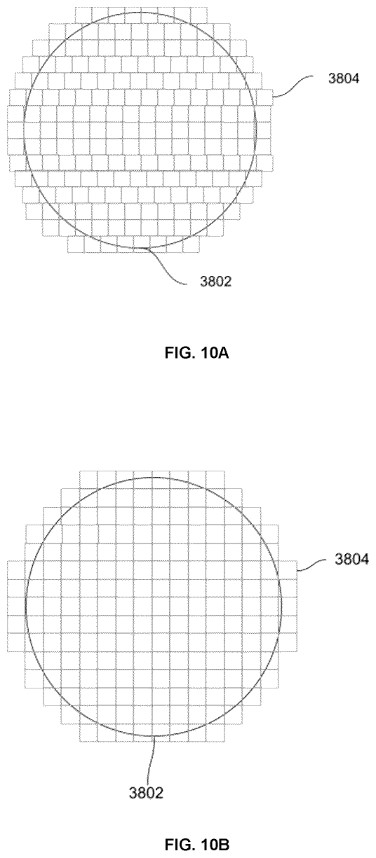

FIG. 10A shows examples of cartridge islands 3802 being different shapes than squares or rectangles. In one related embodiment, the cartridge island 3802 can be circular or oval or other shapes. Here, the microdevice zones 3804 are rectangular or square shapes. In one related embodiment, cartridge island 3802 is populated with microdevices from zones 3804 and each zone 3804 transfer is optimized to cover most of the area inside cartridge island 3802. This may result in a mismatch between microdevices in each zone, affecting the microdevice transfer from the cartridge islands to the system substrate.

FIG. 10B shows an example where zones 3804 are aligned, and enough zones 3804 are used to cover the entire surface of the cartridge island 3802. The area outside the islands can have dummy diaphragm structures to enable the excess area of the zones to be bonded to the cartridge substrate. These microdevices can be removed prior to the transferring microdevices into the system substrate.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method to integrate anchors to hold a microdevice to a substrate, the method comprising;
forming at least two diaphragm layers on the substrate such that the at least two diaphragm structures fit under a microdevice surface wherein the diaphragm structure is smaller than the microdevice surface in at least one dimension; and
bonding the microdevice surface to the diaphragm structures with a bonding layer.

2. The method of claim 1 wherein, an alignment accuracy requirement is reduced as a number of diaphragm layers per microdevice increases.

3. The method of claim 1, wherein the diaphragm layer is formed by depositing a material layer on a patterned release layer.

4. The method of claim 3, wherein the diaphragm layer is a dielectric layer, and the patterned release layer is a metal.

5. The method of claim 1, wherein the bonding layer is formed either on the microdevice or a surface of the diaphragm.

6. The method of claim 5, wherein the bonding layer is a continuous layer, patterned to match a diaphragm pattern or patterned to match the microdevice.

7. The method of claim 6, wherein after the microdevice is bonded to the diaphragm layer, the bonding layer is etched and removed from an excess area not covered by the microdevice.

8. The method of claim 1, wherein after the formation of the diaphragm layer, the surface of the diaphragm is etched away leaving more pillar shape structures on the surface of the microdevice.

9. The method of claim 3, wherein a pattern is interleaved to have more of the diaphragm layer under each microdevice.

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. A method to integrate anchors to hold a microdevice to a cartridge substrate, the method comprising:
depositing release layer on the cartridge substrate;
forming openings in the release layers;
depositing and patterning an anchor and diaphragm layer;
extending at latest part of the diaphragm layer to the release layer opening; and
forming and patterning a bonding layer on top of the diaphragm layer.

32. The method of claim 31, wherein a selected set of microdevices from a donor substrate are aligned with the bonding layer and bonded to it wherein further the donor substrate is removed, and the selected microdevices remain on the cartridge substrate through bonding patterns.

33. The method of claim 32, wherein the process is repeated and other microdevices are aligned and transferred to the cartridge substrate.

34. The method of claim 32, wherein the microdevices are different devices from different donor substrates.

35. The method of claim 32, wherein before transferring the microdevices into a system substrate, the release layer is removed or deformed to enable the transfer.

36. The method of claim 35, wherein a second set of selected microdevices coupled to the cartridge substrate through the bonding layer is aligned with the landing area (or bond pads) on the cartridge substrate and microdevices are bonded to the system substrate through the bond pads.

37. The method of claim 36, wherein the second selected set of microdevices is separated from the cartridge substrate by separating the anchor structure from the cartridge substrate during the bonding process of microdevices to the system substrate or while the cartridge substrate is moved away from the system substrate after bonding.

38. The method of claim 32, wherein the bonding layer is formed on the diaphragm (or anchor) layer or the microdevices on the donor substrate.

39. The method of claim 38, wherein the bonding pattern is formed only for a selected set of microdevices that are transferred to the cartridge substrate.

40. The method of claim 32, wherein the bonding layer is not patterned and after the microdevices are transferred to the cartridge substrate, the microdevice or another layer covering the microdevice is used to pattern the bonding layer.

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)
